(19) United States
(12) Patent Application Publication
(10) Pub. No.: US 2007/0024325 A1
(43) Pub. Date: Feb. 1, 2007

(54) Sense amplifier with input offset compensation

(76) Inventor: Chung-Kuang Chen, Panchiao City (TW)

Correspondence Address: RABIN & Berdo, PC, 1101 14TH STREET, NW, SUITE 500, WASHINGTON, DC, 20005, US

(21) Appl. No.: 11/193,453

(22) Filed: Aug. 1, 2005

(51) Int. Cl. H03F 3/45

(52) U.S. Cl. 327/55

(57) ABSTRACT

A sense amplifier, including a first stage amplifier and a second stage amplifier, for compensating input offset voltage changes due to temperature variation of the sense amplifier. The first stage amplifier receives a data voltage and a reference voltage, and outputs a first data output and a second data output. The first stage amplifier receives an adjusted voltage, and is biased at an internal voltage. The second stage amplifier includes a latch, for level-shifting and amplifying the first and second data output, and is biased at an external voltage. The sense amplifier further includes a bias circuit, for generating the adjusted voltage according to temperature variation of the sense amplifier, to reduce the input offset voltage changes.

### BACKGROUND OF THE INVENTION

1. Field of the Invention

The invention relates in general to sense amplifiers, and more particularly to sense amplifiers with input offset compensation having a amplifier stage and a latch stage.

2. Description of the Related Art

As modern digital systems become more sophisticated and are required to perform multiple tasks, semiconductor memory devices with larger memory storage and higher data accessing speed are inevitably required to address such needs.

In order to achieve high data access speed, one of the solutions is to increase the speed of sense amplifiers in sensing and amplifying data read from memory cells. Sense amplifiers often include differential amplifiers, where the difference between a small voltage sensed from data of a memory cell and a corresponding reference voltage is being amplified, and a proportional voltage is outputted.

However, as the data voltages sensed by the sense amplifier become much smaller so as to reduce device power consumption, the input offset voltage change due to temperature and external power supply variation becomes an important factor to be considered, where the input offset voltage arises as a result of transistor mismatches. That is, the input offset changes can seriously undermine the integrity of differential amplifiers, such that error conditions may occur. For example, a small voltage sensed from a memory cell is originally determined to be a logic “1” when compared to the reference voltage; however, due to the temperature increase in the sense amplifier resulting from long operating time, the input offset voltage that exists between the two differential inputs, being related to temperature, also increases as a result. Consequently, the small voltage sensed from the memory cell is erroneously determined as logic “0”.

Evidently, such errors resulting from input offsets can seriously impact the performance of the overall digital systems, as data from memory cells is being misread.

### SUMMARY OF THE INVENTION

It is therefore an object of the invention to provide a sense amplifier with input offset compensation, where the input offset voltage change due to temperature and external power supply variation is controlled to only vary in a small range.

The invention achieves the above-identified object by providing a sense amplifier for compensating input offset variation. The sense amplifier includes two stages: a first stage amplifier and a second stage amplifier. The first stage amplifier includes an amplifier circuit, preferably a differential amplifier or an OTA amplifier circuit, for receiving a data voltage and a reference voltage, and outputting a first data output and a second data output. The amplifier circuit includes a first MOS transistor, a second MOS transistor, and a third MOS transistor. The first and second MOS transistors are for receiving the data voltage and the reference voltage respectively, and outputting the first data output and the second data output accordingly. The third MOS transistor receives an adjusted voltage, and is biased internally by a first bias circuit at an internal voltage. The internal voltage is pre-determined to yield a small output offset voltage.

The second stage amplifier includes a latch, for amplifying and level shifting the first and second data output received from the first stage amplifier. The latch is biased at an external voltage, where the external voltage is obtained from a source external to the sense amplifier.

The first bias circuit generates the adjusted voltage to be output to the third MOS transistor of the first stage amplifier. The adjusted voltage is generated according to the temperature variation of the sense amplifier for reducing the input offset voltage of the first stage amplifier.

The sense amplifier can further include a second bias circuit for generating voltage biases to be supplied to the NMOS transistors of the first stage amplifier.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 shows a circuit diagram of a sense amplifier according to a first embodiment of the invention;

FIG. 2 is shows a circuit diagram of a sense amplifier according to a second embodiment of the invention;

FIG. 3 shows a simulation diagram illustrating the effects of temperature variation on input offset voltage when the adjusted voltage PBIAS is fixed;

FIG. 4A is a simulation diagram illustrating the effects of temperature variation on input offset voltage when the adjusted voltage PBIAS is not fixed;

FIG. 4B is a simulation diagram showing the adjustments of the adjusted voltage PBIAS as the temperature is varied;

FIG. 5 is a simulation diagram illustrating the effects on the input offset voltages when the internal voltage VCC is varied; and

FIG. 6 shows a simulation diagram of the effects that the conductive states of the pass gates PG1 and PG2 and the transmission gate TG have on DATA0 and DATA1.

### DETAILED DESCRIPTION OF THE INVENTION

### First Embodiment

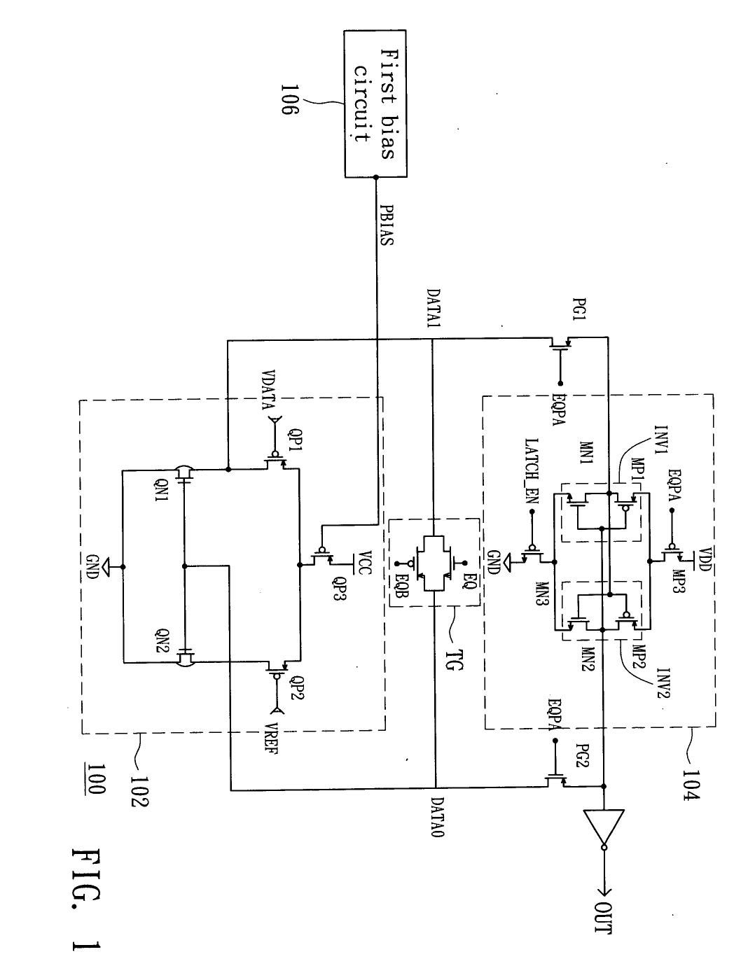

Referring to FIG. 1, a circuit diagram of a sense amplifier 100 according to a first embodiment of the invention is shown. The sense amplifier 100 includes a first stage amplifier 102, including a circuit, a second stage amplifier 104, including a latch, and a first bias circuit 106. The amplifier circuit is used for receiving a data voltage VDATA and a reference voltage VREF. In accordance with the two voltages received, the amplifier circuit outputs a first data output DATA1 and a second data output DATA0 respectively, to be received by second stage amplifier 104.

First stage amplifier 102 includes three MOS transistors, such as a first PMOS transistor QP1, a second PMOS transistor QP2, and third PMOS transistor QP3. The gates of the first and second PMOS transistors QP1 and QP2 receive the data voltage VDATA and the reference voltage VREF respectively. The drains of QP1 and QP2 output the first data output DATA1 and the second data output DATA0, while the sources of QP1 and QP2 are being coupled to the drain of QP3. The gate of QP3 is being biased at an adjusted voltage PBIAS, where the magnitude of PBIAS varies with the temperature variation of the sense amplifier 100. That is, the magnitude of PBIAS increases in response to the temperature. The source of QP3 is biased at an internal voltage VCC, where VCC is supplied internally to the sense amplifier 100. The internal voltage VCC is pre-determined in order to yield a small input offset voltage. Namely, the magnitude of the input offset voltage depends on the magnitude of the internal voltage VCC, such that a decrease in VCC will lead to a decrease in input offset voltage.

First stage amplifier 102 further includes a fourth MOS transistor and a fifth MOS transistor, such as an NMOS transistor QN1, and an NMOS transistor QN2, respectively. The sources of QN1 and QN2 are connected to ground GND. The gates of QN1 and QN2 are connected to each other. The gate and drain of QN2 are also connected to each other, and the drains of the QN1 and QN2 are respectively connected to the drains of QP1 and QP2. Preferably, the threshold voltages of the fourth and fifth MOS transistors QN1 and QN2 are lower than the threshold voltages of the first and second MOS transistors QP1 and QP2. Since voltages VDATA and VREF input to the sense amplifier are often very small, having lower threshold voltages allows QN1 and QN2 to be turned on by lower voltage biases, which are in the case of VDATA and VREF. Alternatively, the fourth and fifth transistors (QN1 and QN2) of the first stage amplifier 102 can be PMOS transistors, in which case the sources of these PMOS transistors are connected to the external voltage VDD.

In addition, second stage amplifier 104 of the sense amplifier 100 is composed of a latch. The latch, coupled to an external voltage VDD, is for amplifying and level-shirting the first and second data outputs DATA0 and DATA1 received from the first stage amplifier 102. The external voltage VDD is supplied externally to the sense amplifier 100, where the voltage level of VDD is substantially equal to the voltage level required to drive other circuits of the electronic device in which the sense amplifier is applied. The advantage of biasing the latch at VDD having voltages different from VCC is so that the signals output by the latch can directly be supplied to other circuits of the electronic devices the sense amplified is applied without having to shift the voltage level. Second stage amplifier 104, being the latch, includes a first inverter INV1 and a second inverter INV2, which are both CMOS inverters. The first inverter INV1 includes a first PMOS transistor MP1 and a first NMOS transistor MN1, while the second inverter INV2 includes a second PMOS transistor MP2 and a second NMOS transistor MN2. The drains of the first PMOS and NMOS transistors MP1 and MN1 are electrically connected to each other, and are for receiving the first data output DATA1. Similarly, the drains of the second PMOS and NMOS transistors MP2 and MN2 are connected to each other, and are for receiving the second data output DATA0. The gates of MP1 and MN1 are connected to each other, and the gates of the MP2 and MN2 are connected to each other. The gates of MP1 and MN1 are connected to the drains of MP2 and MN2, while the gates of MP2 and MN2 are connected to the drains of MP1 and MN1.

Moreover, second stage amplifier 104 further includes a third PMOS transistor MP3 and a third NMOS transistor MN3. The source of MP3 is biased at the external voltage VDD, and the gate of MP3 is for receiving a first control voltage EQPA. The drain of MP3 is connected to both the sources of MP1 and MP2, while the drain of MN3 is connected both the sources of MN1 and MN2. The source of MN3 is connected to ground, and the gate of MN3 receives a second control voltage LATCH_EN. Preferably, MP3 is turned on by the first control voltage EQPA before MN3 is being turned on by the second control voltage LATCH_EN. Thus by doing so, PMOS transistors MP1 and MP2 are also turned on before the NMOS transistors MN1 and MN2 are turned on. Namely, since PMOS transistors characteristically require lower bias voltages to turn on than NMOS transistors, when DATA1 and DATA0 of low voltage levels arrive at the second stage amplifier 104, MP1 and MP2 can first be turned on to operate. Thus, the speed of the latch in amplifying and level shifting the first and second data outputs DATA1 and DATA0 can be effectively increased. Also, another advantage is that since only the PMOS transistors MP1 and MP2 are turned on in the beginning operation of the second stage amplifier, issues regarding NMOS mismatch needs not to be considered. In addition, first bias circuit 106 is coupled to the first stage amplifier 102. More precisely, first bias circuit 106 is coupled to the gate of the third PMOS transistor QP3, and generates the adjusted voltage PBIAS to be supplied to QP3. The adjusted voltage PBIAS is generated according to the temperature variation of the sense amplifier in order to reduce the input offset voltage of the first stage amplifier 102; the magnitude of the input offset voltage is dependent on the magnitude of the adjusted voltage PBIAS.

Sense amplifier 100 further includes a first pass gate PG1 and a second pass gate PG2, which are coupled between first stage amplifier 102 and second stage amplifier 104. The pass gates PG1 and PG2 are for controlling the transmission of the first and second data output DATA1 and DATA0 respectively. The first control voltage EQPA controls PG1 and PG2, so that PG1 and PG2 are turned on to allow data transmission after the DATA0 and DATA1 outputted by first stage amplifier 102 have reached a stable state. Thus, DATA1 and DATA0 cab be transmitted from the first amplifier stage 102 to the second amplifier stage 104. PG1 and PG2 are being turned off to disallow transmission after DATA1 and DATA0 are received by the latch of second stage amplifier 104. Thus, the voltages input and output by the latch can be unaffected, or independent, from any DATA1 and DATA0 further outputted by first amplifier stage 102.

Additionally, sense amplifier 100 further includes a CMOS transmission gate TG. The transmission gate TG is configured such that when it is being turned on, DATA1 and DATA0 inputting to the second stage amplifier 104 become equal in voltage level. By doing so, the transmission gate TG effectively resets the value of DATA1 and DATA0 entering the second stage amplifier 104.

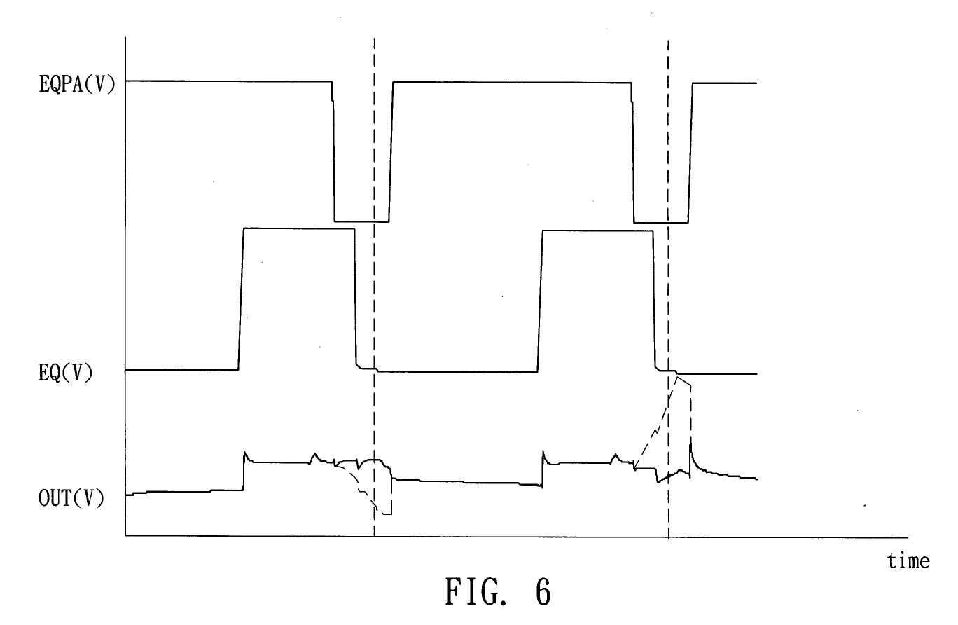

FIG. 6 shows a simulation diagram of the effects that the conductive states of the pass gates PG1 and PG2 and the transmission gate TG have on DATA0 and DATA1. As shown in FIG. 1, the pass gates PG1 and PG2 are biased at EQPA, and the transmission gate TG is biased at EQ. The voltage waveform of EQPA and EQ are shown by respective plots in FIG. 6. The voltage levels of DATA0 and DATA1 at the second stage amplifier output OUT are shown on the same plot as solid and dotted lines, respectively. Referring both to FIG. 1 and FIG. 6, after the first and second data outputs outputted by the first stage amplifier has reached a stable state, the voltage level of EQ goes low, and the transmission gate TG is turned on. Whence, the voltage levels of DATA0 and DATA1 within the corresponding time interval, connected to the input and output of the transmission gate, are being set to equal as the transmission gate TG is turned on, thereby effectively completing voltage reset.

When the voltage of EQPA is low, the pass gates PG1 and PG2 are consequently turned on. Thus, DATA1 and DATA0 can be output from the first stage amplifier 102 to the second stage amplifier 104 via the pass gates PG1 and PG2 respectively, as reflected by the voltage levels of DATA0 and DATA1 at Vout within the corresponding time to be relatively different from each other.

In brief, through auto-adjusting the adjusted voltage PBIAS by the first bias circuit in response to temperature variation of the sense amplifier, the sense amplifier according to this embodiment of the invention effectively compensates for input offset voltage changes due to temperature variation.

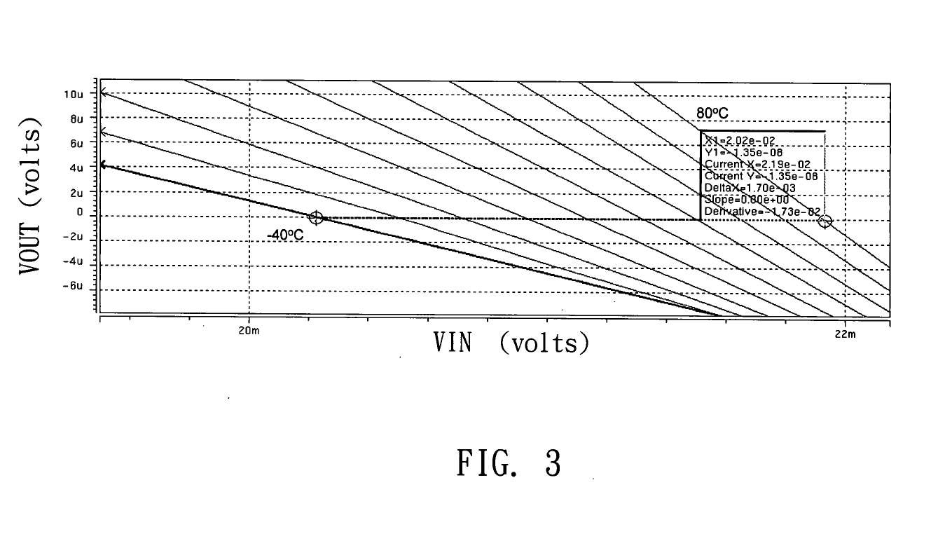

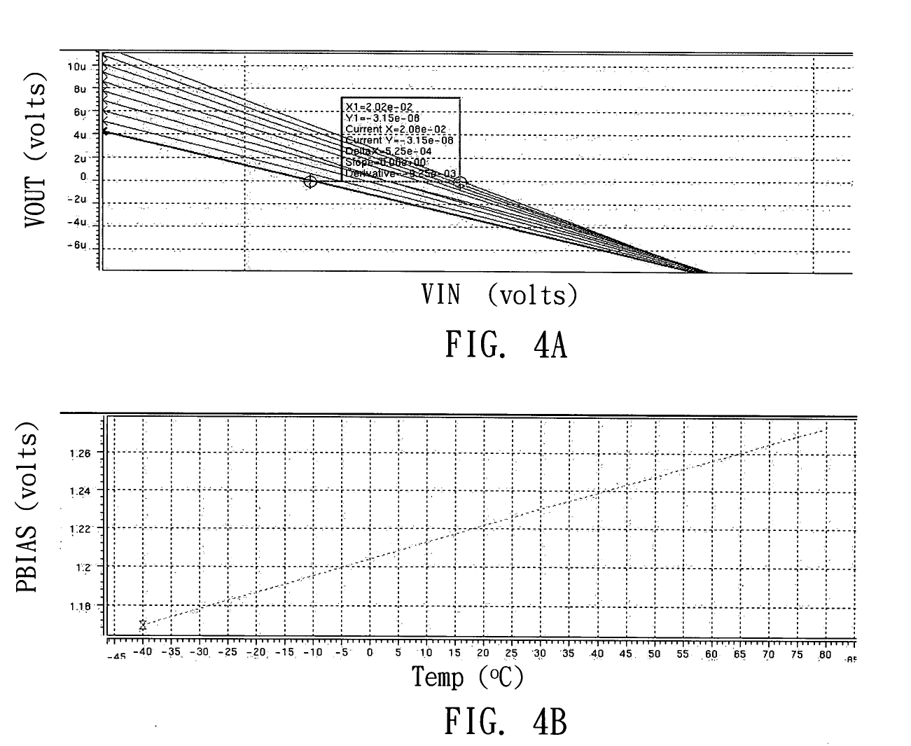

To better understand the effects of input offset voltages compensation through PBIAS adjustments, the following simulation diagrams are provided. FIG. 3 shows a simulation diagram illustrating the effects of temperature variation on input offset voltage when PBIAS is fixed at 1.7V. The horizontal axis denotes the difference in voltage between the VDATA and VREF, where the difference is denoted as the input voltage VIN. The vertical axis denotes the output voltage VOUT, being the difference in voltage between DATA1 and DATA0. The input offset voltage is the VIN when VOUT equals to 0V. As shown in FIG. 3, as temperature goes from −40° C. to 80° C., the input offset voltage increases significantly, from about 20.2 mV to about 21.9 mV, which translates to an 8% variation. However, when PBIAS is being adjusted to change according to temperature variation of the sense amplifier, the effects can be seen in FIGS. 4A and 4B.

FIG. 4A shows a diagram illustrating the effects of temperature variation on input offset voltage when PBIAS is not fixed. The horizontal axis denotes the difference in voltage between the VREF and VDATA, or VIN. The vertical axis denotes the output voltage VOUT, which is the difference in voltage between DATA1 and DATA0. Each individual curve in FIG. 4A corresponds to a VOUT versus VIN relationship of the amplifier circuit at a particular temperature, with the left-most curve corresponding to the temperature at −40° C., and the right most curve corresponding to the temperature at 80° C. FIG. 4B shows the adjustments of PBIAS as the temperature of the amplifier increases. The horizontal axis denotes the change in temperature, and the vertical axis denotes the change in PBIAS. In FIG. 4B, as PBIAS is varied from about 1.17V to about 1.27V in response to temperature variation from −40° C. to 80° C. of the sense amplifier. The change in input offset voltage is observed in FIG. 4A. The input offset varies in a much smaller range from about 20.2 mV to about 20.8 mV, which translates to a variation of less than 1%. Thus, as demonstrated, through design by adjusting the level of PBIAS, the sense amplifier of the present invention can effectively compensate for the input offset voltage changes due to temperature variation of the sense amplifier.

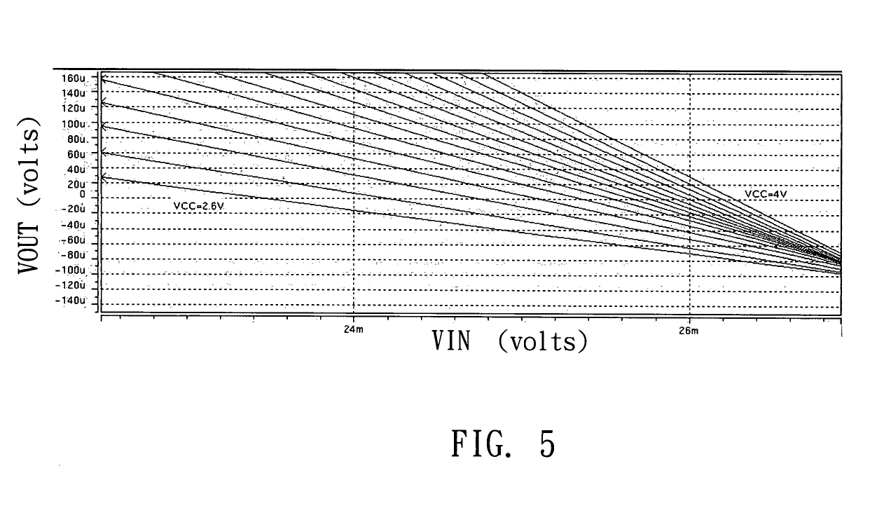

Referring to FIG. 5, the effects on the input offset voltages while VCC is varied is shown in a simulation diagram. In FIG. 5, the horizontal axis denotes the input offset voltage VIN and the vertical axis denotes the output voltage VOUT. When the internal voltage VCC is varied from 2.6V to 4V- under constant PBIAS of 1.17V, the trend of input offset voltage VIN reflected an increase, varying from approximately 23.4 mV to 27 mV, which translates roughly to a 15% change. From FIG. 5, it is apparent that if the input offset were to be minimized, then a lower VCC should be selected. Hence, by choosing a low VCC combined with the adjustments of PBIAS according to temperature variation to compensate for input offset variation, the problem of data from memory cells being misread by the sense amplifier can be prevented. That is, since supplying the first stage amplifier 102 with an external biasing voltage would, due to external conditions, cause the biasing voltage level to vary within a range and give rise to an input voltage offset; thus, an alternatively chosen internal voltage VCC is selected, and as demonstrated in FIG. 5, can effectively minimize the input voltage offset.

### Second Embodiment

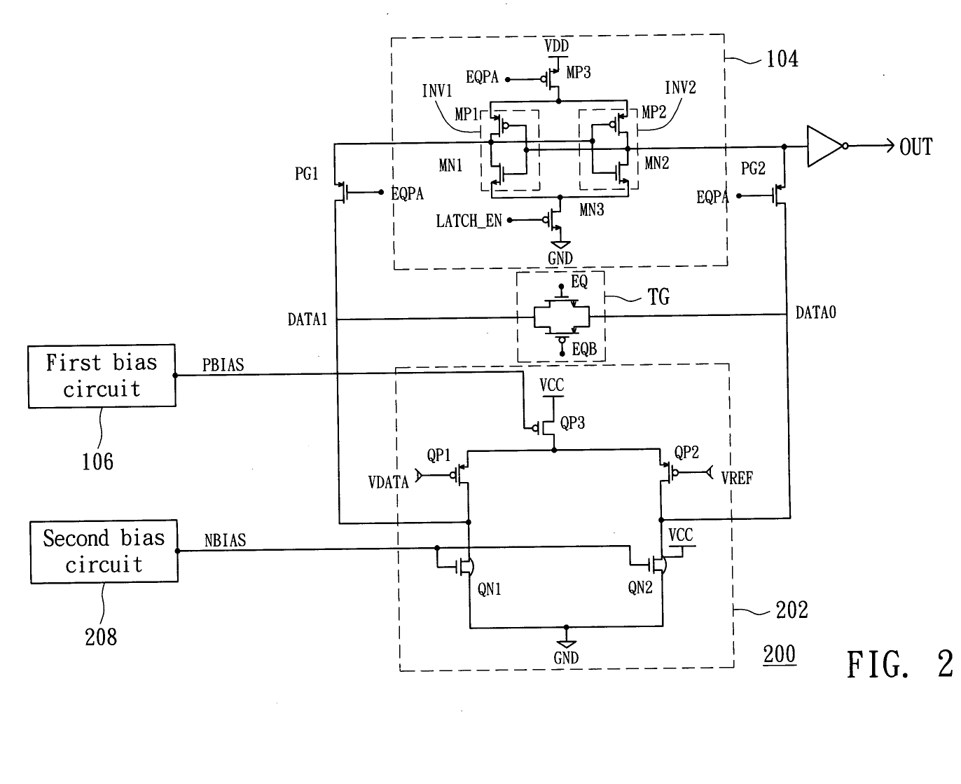

FIG. 2 shows a sense amplifier according to a second embodiment of the invention. The sense amplifier 200 includes a first stage amplifier 202 and a second stage amplifier 204, and is distinguished from the first embodiment in that the sense amplifier 200 further includes a second bias circuit in 208. Instead of connecting to the drain of QP2 as of FIG. 1, the gates of the fourth and the fifth MOS transistors QN1 and QN2 alternatively receive voltage biases NBIAS generated from the second bias circuit 208. QN1 and QN2 are used at the loading for the first stage amplifier 202.

In summary, the sense amplifier according to the invention have the following advantages:

1. Reduced power consumption and increased operation speed

While the latch requires a higher voltage bias (external voltage) to operate, the differential amplifier is ideal to be biased at a lower voltage (internal voltage) in order to reduce input offset voltage, as illustrated by FIG. 5. Thus, by biasing the second stage amplifier and the first stage amplifier separately, lower power consumption and lower input offset voltage can be achieved. Also, since the latch of the second stage amplifier in both embodiments are implemented with PMOS transistors that can be turned on even by low bias voltages, for that reason, the latch of the second stage amplifier can quickly amplify and level shift signals DATA1 and DATA0 received from the first stage amplifier, thereby increasing the speed of the overall sense amplifier operation.

2. Wider acceptable input common mode voltage range

Since using the PMOS transistors to be the input device, the input voltage range acceptable by the differential amplifier in common mode is wider, thus allowing data sensed by the sense amplifier from memory cells to have lower voltage levels.

3. Input offset compensation due to temperature and external power supply variation

Since simulation diagrams of FIGS. 3, 4A, 4B and 5 demonstrated that the input offset variation range can be reduced significantly by adjusting the adjusted voltage PBIAS combined with low VCC, the sense amplifier of the invention utilized the bias circuit to generate PBIAS voltages in response to temperature variation, thereby effectively compensating for input offset variation.

4. Reliable

By using the pass gates PG1 and PG2 to control the transmission of the first and second data output DATA1 and DATA0 respectively, the voltages input and output by the latch can be unaffected from any DATA1 and DATA0 further outputted by first amplifier stage 102, thereby ensuring the integrity, or reliability, of the sense amplifier.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A sense amplifier, comprising: a first stage amplifier, comprising an amplifier circuit, for receiving a data voltage and a reference voltage, and outputting a first data output and a second data output, the first stage amplifier being biased at an internal voltage in order to yield a small input offset voltage, the magnitude of the input offset voltage being dependent on the internal voltage substantially; and
a second stage amplifier comprising a latch, for amplifying and level shifting the first data output and the second data output of the first stage amplifier, the latch being biased at an external voltage.

2. The sense amplifier according to claim 1, wherein the amplifier circuit comprises a first MOS transistor, a second MOS transistor, and a third MOS transistor, the gates of the first and second MOS transistors receive the data voltage and the reference voltage respectively, the drains of the first and second MOS transistors output the first data output and the second data output according to the data voltage and the reference voltage respectively, the sources of the first and second MOS transistor are coupled to the drain of the third MOS transistor, the gate of third MOS transistor is biased at an adjusted voltage whose magnitude varies with the temperature variation of the sense amplifier, the source of the third MOS transistor being biased at the internal voltage.

3. The sense amplifier according to claim 1, wherein the first, second and third MOS transistors can be PMOS transistors.

4. The sense amplifier according to claim 1, wherein the first, second and third MOS transistors can be NMOS transistors and the source of the third MOS being biased at the ground

5. The sense amplifier according to claim 3, wherein the first stage amplifier further comprises a fourth NMOS transistor and a fifth NMOS transistor, the sources of the fourth and the fifth NMOS transistors of the first stage amplifier are connected to ground, the gates of the first fourth and second fifth NMOS transistors are connected to each other, the gate and the drain of the fifth NMOS transistor are connected to each other, the drains of the fourth and fifth NMOS transistors are respectively connected to the drains of the first and second PMOS transistors.

6. The sense amplifier according to claim 4, wherein the first stage amplifier further comprises a fourth PMOS transistor and a fifth PMOS transistor, the sources of the fourth and the fifth PMOS transistors of the first stage amplifier are connected to the external voltage, the gates of the fourth and fifth PMOS transistors are connected to each other, the gate and the drain of the fifth PMOS transistor are connected to each other, the drains of the fourth and fifth PMOS transistors are respectively connected to the drains of the first and second NMOS transistors.

7. The sense amplifier according to claim 5, wherein the threshold voltages of the fourth and fifth MOS transistors are lower than that of the first and second MOS transistors.

8. The sense amplifier according to claim 2, wherein the sense amplifier further comprises a first bias circuit for generating the adjusted voltage.

9. The sense amplifier according to claim 8, wherein the first bias circuit generates the adjusted voltage to be output to the gate of the third MOS transistor, the gate and the drain of the fifth MOS transistor being connected to each other, the adjusted voltage being generated according to the temperature variation of the sense amplifier, the magnitude of the input offset voltage being dependent on the magnitude of the adjusted voltage substantially.

10. The sense amplifier according to claim 8, wherein the sense amplifier further comprises a second bias circuit generating voltage biases to be output to the gates of the fourth and the fifth MOS transistors and in this condition the drains of the fourth and fifth MOS transistors are not respectively connected

11. The sense amplifier according to claim 1, wherein the latch of the second stage amplifier comprises a first inverter and a second inverter, the first and second inverters are CMOS inverters, the first inverter comprises a first PMOS transistor of the first inverter, and a first NMOS transistor of the first inverter, the second inverter comprising a second PMOS transistor of the second inverter, and a second NMOS transistor of the second inverter, the drains of the first PMOS and NMOS transistors of the first inverter being connected to each other, for receiving the first data output, the drains of the second PMOS and the second NOMOS transistors of the second inverter being connected to each other, for receiving the second data output, the gates of the first PMOS and NMOS transistors of the first inverter being connected to teach other, and the gates of the second PMOS and NMOS transistors of the second inverter being connected to each other, the gates of the first PMOS and NMOS transistors of the first inverter also being connected to the drains of the second PMOS and NMOS transistors of the second inverter, the gates of the second PMOS and NMOS transistors of the second inverter also being connected to the drains of the first PMOS and NMOS transistors of the first inverter.

12. The sense amplifier according to claim 1, wherein the second stage amplifier further comprises a third PMOS transistor of the second stage amplifier and a third NMOS transistor of the second stage amplifier, the source of the third PMOS transistor of the second stage amplifier is biased at the external voltage, that gate of the third PMOS transistor of the second stage amplifier receives a first control voltage, the drain of the third PMOS transistor of the second stage amplifier is connected to both the sources of the first and second PMOS transistors, the drain of the third NMOS transistor of the second stage amplifier is connected to both the sources of the first and second NMOS transistors of the second stage amplifier, the source of the third NMOS transistor of the second stage amplifier is connected to ground, and the gate of the third NMOS transistor of the second stage amplifier receives a second control voltage.

13. The sense amplifier according to claim 12, wherein the third PMOS transistor of the second stage amplifier is turned on by the first control voltage before the third NMOS transistor of the second stage amplifier are turned on by the second control voltage if the output voltage of the first stage amplifier is lower than 0.5*VDD.

14. The sense amplifier according to claim 12, wherein the third NMOS transistor of the second stage amplifier is turned on by the first control voltage before the third PMOS transistor of the second stage amplifier are turned on by the second control voltage if the output voltage of the first stage amplifier is higher than 0.5*VDD.

15. The sense amplifier according to claim 1, wherein the sense amplifier further comprises a first pass gate and a second pass gate coupled between the first stage amplifier and the second stage amplifier, for controlling the transmission of the first and the second data output respectively, the first and the second pass gates being controlled by the first control voltage such that the first and second pass gates are turned on after the first and second data outputs outputted by the first stage amplifier has reached a stable state, allowing the first and second data outputs to be transmitted from the first amplifier stage to the second amplifier stage, and the first and second pass gates are being turned off after the first and second data outputs are received by the latch of the second stage amplifier, allowing the voltages input and output by the latch to be independent of the first and the second data outputs further outputted by the first amplifier stage.

16. The sense amplifier according to claim 1, wherein the sense amplifier further comprises a transmission gate configured such that when the transmission gate is turned on, the first data output and the second data output inputting to the second stage amplifier become equal in voltage level.

17. The sense amplifier according to claim 1, wherein the internal voltage is obtained from a source internal to the sense amplifier.

18. The sense amplifier according to claim 1, wherein the external voltage is obtained from a source external to the sense amplifier.

19. The sense amplifier according to claim 1, wherein the amplifier circuit of the first stage amplifier is an OTA (operational trans-conductance) amplifier circuit.

20. The sense amplifier according to claim 1, wherein the amplifier circuit of the first stage amplifier is a differential amplifier circuit.
